(19) United States
(12) Patent Application Publication
(10) Pub. No.: US 2012/0144634 A1
(43) Pub. Date: Jun. 14, 2012

(54) METAL OXIDE VARISTOR DESIGN AND ASSEMBLY

(76) Inventors: Bruce Charles Barton, Huntington, NY (US); Russell Barton, Northport, NY (US)

(21) Appl. No.: 12/968,063

(22) Filed: Dec. 14, 2010

(51) Int. Cl. H01L 21/00

(52) U.S. Cl. 29/25.01

(57) ABSTRACT

Spacing of metal oxide varistors (“MOVs”) when used for surge suppression or surge protection will determine the number that can be used and the amount of protection achieved in a limited space. By changing the way the leads are attached to the metal oxide varistors (“MOVs”), tighter spacing, higher densities, and more surge suppression and protection can be placed in the same sized location. Leads are attached to metal oxide varistors (“MOVs”) to allow the metal oxide varistors (“MOVs”) to be placed side by side without the lead of one metal oxide varistor (“MOV”) interfering with the lead of a different metal oxide varistor (“MOV”)

### BACKGROUND OF THE INVENTION

1. Technical Field of the Invention

The present invention relates, generally, to the manufacture of metal oxide varistors (“MOVs”) and the assembly of metal oxide varistors (“MOVs”) for use in surge suppression or surge protection, which provides increased part density, as compared to similar current methods.

2. Description of the Prior Art

Presently, metal oxide varistors (“MOVs”) placed side by side with spacing for the legs and insulating coating between them. Metal oxide varistors (“MOVs”) are also some made into modules with two or more layered and sharing a common lead.

During normal assembly of a surge suppression or surge protection device the metal oxide varistors (“MOVs”) are placed side by side with wide enough spacing for the leads and epoxy covering. This limits the number of metal oxide varistors (“MOVs”) are placed inside the units.

Luo, U.S. Pat. No. 7,623,019, issued Nov. 24, 2009, discloses method of assemble of 3 metal oxide varistors (“MOVs”) sandwiched with 2 common leads between the metal oxide varistors (“MOVs”). It is difficult in manufacturing to keep the metal oxide varistors (“MOVs”) parallel during assembly making manufacturing an expensive and difficult process.

### SUMMARY OF THE INVENTION

It is, therefore an object of the present invention to provide a method of manufacturing and assembly without the limitations of the prior methods above.

By manufacturing metal oxide varistors (“MOVs”) with offset leads and also making them with opposite facing leads, the metal oxide varistors (“MOVs”) can be interlock during assembly. Interlocking the metal oxide varistors (“MOVs”) during assembly allows more metal oxide varistors (“MOVs”) in a smaller space without the added cost joining the metal oxide varistors (“MOVs”) in to one part. Interlocking the metal oxide varistors (“MOVs”) also does not require the metal oxide varistors (“MOVs”) to be epoxy coated because touching surfaces are electrically connected.

### DESCRIPTION OF THE DRAWING FIGURES

FIG. 1 shows how 3 metal oxide varistors (“MOVs”) would normally be placed with the spacing between them.

FIG. 2 is prior art from Luo, U.S. Pat. No. 7,623,019. Luo shows 3 metal oxide varistors (“MOVs”) sharing 2 common leads in the center and two single lead on each end. This allows the metal oxide varistor (“MOVs”) spacing to be more dense than FIG. 1, but has an added cost of a difficult and expensive manufacturing process.

FIG. 3 is a drawing of two metal oxide varistors (“MOVs”), the one on the left is a front left, wide lead pattern; and the one on the right is a front right, narrow lead pattern. Also shown in this drawing, the metal oxide varistor (“MOV”) on the left has the leads crossing above center and the metal oxide varistor (“MOV”) on the right has the leads crossing below center. The arrangement of the leads, being wide and above center, and narrow and bellow center, allows the metal oxide varistors (“MOVs”) to be spaced as close to together as in FIG. 2 with the difficult and expensive manufacturing cost of a single lead.

FIGS. 4 and 5 shows a side and bottom view of the 2 metal oxide varistors (“MOVs”) arranged tight together without the leads interfering with each other. This is how they are arranged when installed in to the printed circuit board. Because the two leads between the metal oxide varistors (“MOVs”) can be connected together on the print circuit board, the metal oxide varistors (“MOVs”) do not need to be epoxy coated.

FIGS. 6 and 7 shows a side and bottom view of the 4 metal oxide varistors (“MOVs”) arranged tight together without the leads interfering with each other.

FIG. 8 is a drawing of two of the same type of metal oxide varistors(“MOV”), the view on the left shows a left attached lead, wide and above center; and the view on the right shows a right attached lead, narrow and below center. The arrangement of the leads, being wide and above center on one side, narrow and bellow center on the other side, again allows the metal oxide varistors (“MOVs”) to be spaced as close to together as in FIG. 2 with the difficult and expensive manufacturing cost of a single lead.

FIGS. 9 and 10 shows a side and bottom view of the 2 metal oxide varistors (“MOVs”) of the type shown in FIG. 8 arranged tight together without the leads interfering with each other. Here just 2 are shown, but any number of metal oxide varistors (“MOVs”) may be stacked.

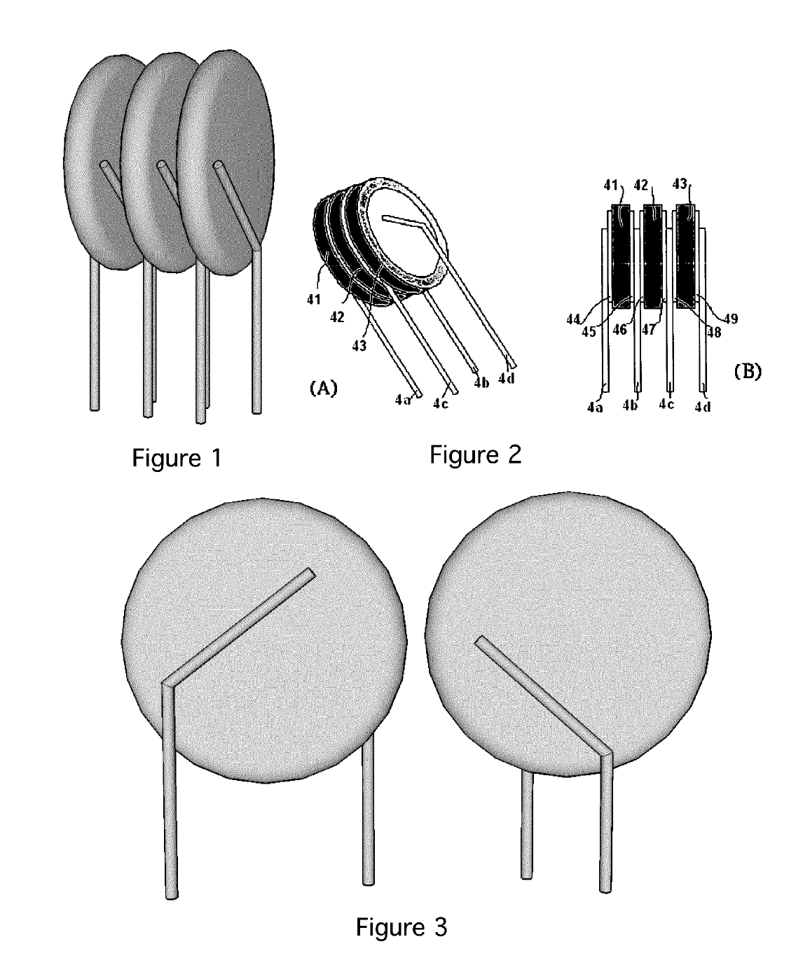

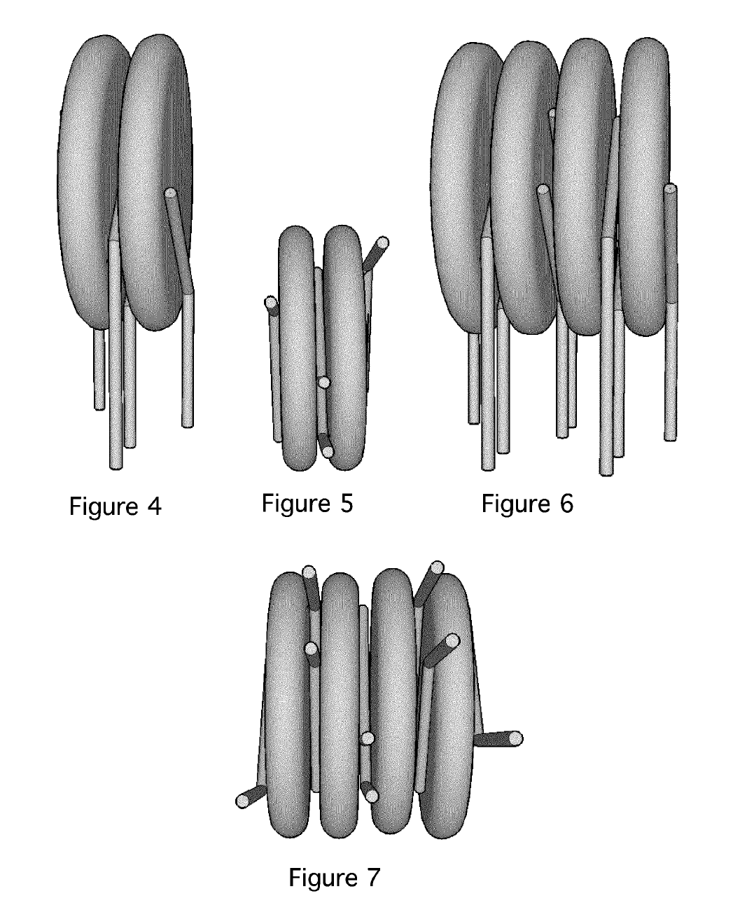

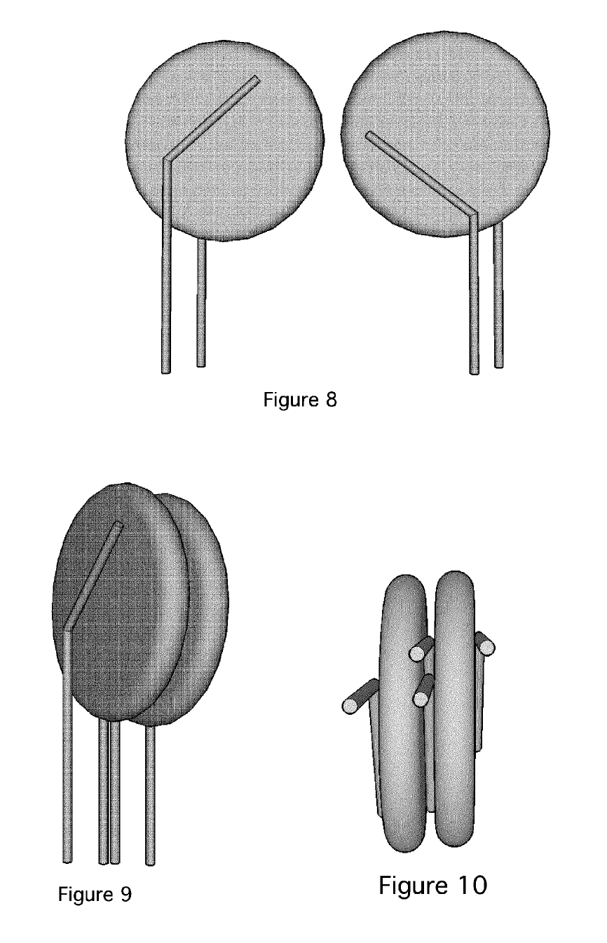

What is claimed is:

1. A manufacture of metal oxide varistors (“MOVs”) with leads attach in a way to allow tight grouping without the leads interfering in the spacing.

2. The manufacture of metal oxide varistors (“MOVs”) according to claim 1, where the leads are mounted on the left side, wider and higher on the faces of the metal oxide varistor (“MOV”) and where the leads are mounted on the right side, narrower and lower on the faces of a different metal oxide varistor (“MOV”).

3. The manufacture of metal oxide varistors (“MOVs”) according to claim 1, where the leads are mounted on the right side, wider and higher on the faces of the metal oxide varistor (“MOV”) and where the leads are mounted on the left side, narrower and lower on the faces of a different metal oxide varistor (“MOV”).

4. The manufacture of metal oxide varistors (“MOVs”) according to claim 1, where the leads are mounted asymmetrically on each face of the metal oxide varistor (“MOV”) to allow tight grouping without the leads interfering in the spacing.

5. The mounting of metal oxide varistors (“MOVs”) manufactured with offset leads described in claim 1 for surge suppression or surge protection in tight grouping pattern without the leads interfering in the spacing.

6. The mounting of metal oxide varistors (“MOVs”) according to claim 5 where the metal oxide varistors (“MOVs”) are mounted to a printed circuit board.

7. The mounting of metal oxide varistors (“MOVs”) according to claim 5 where the metal oxide varistors (“MOVs”) are mounted to wire or metal busses.

8. The mounting of metal oxide varistors (“MOVs”) according to claim 5 where the metal oxide varistors (“MOVs”) are mounted inside a case.

9. The mounting of metal oxide varistors (“MOVs”) according to claim 8 the case is a ceramic case.

10. The mounting of metal oxide varistors (“MOVs”) according to claim 9 the case is a pre-made ceramic case and the metal oxide varistors (“MOVs”) are placed inside.

11. The mounting of metal oxide varistors (“MOVs”) according to claim 8 the case is a concrete or cement.

12. The mounting of metal oxide varistors (“MOVs”) according to claim 11 the case is a pre-made concrete or cement and the metal oxide varistors (“MOVs”) are placed inside.

13. The mounting of metal oxide varistors (“MOVs”) according to claim 8 the case is poured around the metal oxide varistors (“MOVs”).

14. The mounting of metal oxide varistors (“MOVs”) according to claim 5 where the assembled metal oxide varistors (“MOVs”) are dip to a casing material.

15. The mounting of metal oxide varistors (“MOVs”) according to claim 14 where the incasing material is epoxy.
